(19) United States
(12) Patent Application Publication
(10) Pub. No.: US 2005/0272218 A1
(43) Pub. Date: Dec. 8, 2005

(54) Method of forming metal lower electrode of a capacitor and method of selectively etching a metal layer for the same

(75) Inventors: Young-Rae Park, Suwon-si (KR); Young-Ho Koh, Yongin-si (KR); Chang-Ki Hong, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/145,308

(22) Filed: Jun. 3, 2005

(30) Foreign Application Priority Data
Jun. 7, 2004 (KR) 2004-41437

(51) Int. Cl. H01L 21/20

(52) U.S. Cl. 438/386

(57) ABSTRACT

A method of forming a cylindrical lower electrode of a capacitor in which metal is used as a lower electrode of a capacitor. A metal capping layer is used in order to protect the inner walls of the cylindrical metal lower electrode. A sacrificial insulating layer is patterned to form an aperture for forming the lower electrode. A metal lower electrode layer and the metal capping layer are sequentially formed. In order to electrically separate adjacent metal lower electrodes from each other, the metal capping layer and the metal lower electrode layer are simultaneously planarized until the sacrificial insulating layer is exposed. The sacrificial insulating layer and the metal capping layer that resides in the aperture are removed such that the cylindrical metal lower electrode having inner and outer walls is completed. Therefore, it is possible to simultaneously palanarize the metal capping layer and the metal lower electrode layer with respect to the sacrificial insulating layer such that it is possible to simplify processes for forming the lower electrodes.

### CROSS-REFERENCE TO RELATED APPLICATIONS

The present application claims priority from Korean Patent Application 2004-41437 filed on Jun. 7, 2004, the entire contents of which are hereby incorporated herein by reference.

### BACKGROUND OF THE INVENTION

The present disclosure relates to a method of manufacturing a semiconductor apparatus, and more particularly, to a method of forming a metal lower electrode of a capacitor and a method of selectively etching a metal layer for the same.

Since semiconductor apparatuses are highly integrated, the area of unit elements formed on a wafer of a given size is reduced. Therefore, the area of capacitors is also reduced. A capacitor can be used for a memory device and is comprised of two electrodes that face each other and a dielectric layer between the two electrodes. Silicon can be used as a capacitor electrode. The capacitor requires a capacitance of a certain level.

The capacitance is related to a thickness of the dielectric layer, a dielectric constant of the dielectric layer, and a surface area of the electrodes. The smaller the thickness of the dielectric layer is, the higher the dielectric constant is, and the larger the surface area of the electrodes is, the larger the capacitance is. As the semiconductor apparatuses are highly integrated, the area occupied by the capacitors is reduced. Therefore, the capacitance is also reduced. Considering the above, many efforts are made to increase the capacitance. In order to increase the capacitance, the thickness of the dielectric layers can be reduced, a dielectric layer having high dielectric constant can be used, and the surface area of the electrodes can be increased.

Among the above, a three-dimensional silicon lower electrode can be formed to increase the surface area of the electrodes. As a representative example, the lower electrode is made cylindrical. Since an inner surface (inner walls) and an outer surface (outer walls) of the cylindrical silicon lower electrode are used as the effective electrode area of the capacitor, the capacitance increases.

According to a known method of forming the cylindrical silicon lower electrode, a capping layer for protecting a sacrificial insulating layer and the cylindrical silicon lower electrode is used. In order to electrically separate a cylindrical silicon lower electrode from an adjacent lower electrode, a planarization process is performed. Also, in order to expose the outer walls and the inner walls of the cylindrical silicon lower electrode, the capping insulating layer and the sacrificial insulating layer are removed. That is, after forming an aperture by patterning the sacrificial insulating layer and then, forming silicon and the capping insulating layer, the silicon and the capping insulating layer are etched to be planarized by a chemical mechanical polishing (CMP) process until the sacrificial insulating layer is exposed. The sacrificial insulating layer and the capping insulating layer are commonly formed of a silicon oxide layer. As is known, silicon and an oxide layer may be simultaneously etched to be planarized by slurry.

However, due to continuous reductions in design, the capacitor dielectric layer has been formed of high dielectric material having a high dielectric constant in order to increase the capacitance. An interface characteristic between the high dielectric layer having the high dielectric constant and the silicon used as the lower electrode is poor. Also, when the silicon is used as the lower electrode, a depletion region is generated in the silicon lower electrode such that leakage current may increase. As a result, the capacitance is reduced.

Therefore, a method of using metal as the lower electrode instead of the conventional silicon lower electrode has been applied. For example, FIGS. 1 to 4 are sectional views of a semiconductor substrate illustrating the method of forming the capacitor having the metal lower electrode. Hereinafter, the conventional method of forming the capacitor using the metal lower electrode will be described with reference to FIGS. 1 to 4.

First, referring to FIG. 1, an interlayer insulating layer 10 including a contact plug 12 is formed on a semiconductor substrate (not shown). A sacrificial insulating layer 14 is formed to be patterned such that a contact hole 16 that confines a lower electrode is formed in the sacrificial insulating layer 14. At this time, the height of the contact hole 16 determines the height of the lower electrode. The sacrificial insulating layer 14 is formed of, for example, a silicon oxide layer.

Next, referring to FIG. 2, a metal layer 18 to be used as the lower electrode is formed along the contact hole 16 and a capping layer 20 is formed on the metal layer 18 such that the contact hole 16 is completely filled with the capping layer 20. The capping layer 20 is formed of, for example, an insulating layer such as the silicon oxide layer.

Next, referring to FIG. 3, the capping layer 20 is selectively etched by performing, for example, an etchback process such that the capping layer 20′ remains only inside the contact hole 16. That is, the capping layer 20′ is recessed into the inside of the contact hole and the metal layer outside the contact hole is exposed.

Next, referring to FIG. 4, the CMP process is performed on the metal layer 18 such that the metal layer outside the contact hole 16 is removed and the metal layer remains only in the contact hole 16 such that a metal lower electrode 18′ electrically separated from adjacent lower electrodes is formed.

In subsequent processes, the capping layer 20′ that resides in the contact hole 16 and the sacrificial insulating layer 14′ are removed and an insulating layer and an upper electrode layer are sequentially formed.

According to the above-described conventional method of forming the capacitor having the metal lower electrode, the capping layer 20 having high etching selectivity with respect to the lower electrode material is formed in order to prevent the lower electrode from being etched during the CMP process and to prevent defects from being generated in the cylinder (the contact hole).

Since the capping layer 20 and the metal layer 18 are not simultaneously etched, after the etch back process is performed on the capping layer 20 to expose the metal layer outside the contact hole 16, the CMP process is performed on the exposed metal layer. Here, as a result of performing the etchback process on the capping layer 20, the capping layer 20′ is recessed into the contact hole 16. That is, the height of the recessed capping layer 20′ is less than the height of the sacrificial insulating layer 14.

Therefore, during the CMP process for electrically separating the adjacent lower electrodes from each other, a part of the sacrificial insulating layer 14 is etched. As a result, a part of the metal layer 18 in the contact hole 16 is also etched. That is, the height of the lower electrode is reduced such that the capacitance is reduced.

A step difference may be generated between a peripheral circuit region in which the capacitor is not formed and a cell region in which the capacitor is formed. That is, the height of the capping layer 20 in the cell region may be larger than the height of the capping layer in the peripheral circuit region. In such a case, as a result of performing the etch back process on the capping layer 20, the height of the recessed capping layer in the peripheral circuit region is less than the height of the capping layer 20′ in the cell region. Therefore, when a step difference exists between the cell region and the peripheral circuit region, the amount of the metal layer etched in the CMP process is larger than the amount of the metal layer etched in the CMP process when a step difference does not exist.

Also, the capping layer 20′ is recessed into the contact hole 16 such that defects such as process slurries may remain in the contact hole from the CMP process. Therefore, the slurries may be attached to the inner walls of the metal lower electrode 18′ in subsequent processes of removing the capping layer and the sacrificial insulating layer.

Also, according to the conventional art, since the etch back process must be performed on the capping layer and the CMP process must be performed on the metal layer in order to separate the metal lower electrodes from each other, processes become complicated and ultimately throughput is reduced. Furthermore, since the CMP process and the etchback process cannot be performed using the same equipment, a substrate must be transmitted from one piece of equipment to another such that the substrate may be contaminated by minute contaminants in the air.

### SUMMARY OF THE INVENTION

It is an object of the embodiments of the present invention to provide a method of forming a metal lower electrode capable of simply securing high capacitance.

In a method of forming a metal lower electrode according to an embodiment of the present invention, a metal layer is used as a capping layer. A metal capping layer and a metal lower electrode layer can be simultaneously etched such that adjacent lower electrodes are electrically separated from each other by performing a chemical mechanical polishing (CMP) process once. That is, it is not necessary to perform an etchback process on the capping layer. Therefore, problems associated with the etchback process are avoided.

A method of forming a lower electrode of a capacitor according to an embodiment of the present invention comprises forming a sacrificial insulating layer on a semiconductor substrate including a conductive region, patterning the sacrificial insulating layer to form an aperture that exposes the conductive region, forming a first metal layer along the sides and the bottom of the aperture and the top surface of the sacrificial insulating layer, forming a second metal layer on the first metal layer such that the aperture is filled with the second metal layer, performing a planarization process on the second metal layer and the first metal layer until the sacrificial insulating layer is exposed, and selectively removing the second metal layer that resides in the aperture to expose the inner walls of the first metal layer.

According to the method of forming the metal lower electrode, since the first and the second layers are metal layers, a selective planarization process can be performed on the sacrificial insulating layer using a metal layer removing slurry. The metal layer removing slurry includes an oxidizer and an abrasive. Hydrogen peroxide may be used as the oxidizer that oxidizes metal. The metal is oxidized by the oxidizer such that a weak metal oxide layer is formed. The abrasive removes the weak metal oxide layer from a substrate by abrasive force due to the relative mechanical motion of a polishing pad with respect to the substrate. Al₂O₃, SiO₂, or the like may be used as grains of the abrasive. The slurry may further include sulfuric acid, nitric acid, and hydrochloric acid as a pH controller.

For example, the slurry in the range of between about pH 1 and about pH 5, whose etching ratio of the sacrificial insulating layer to metal is about 1:10 or more and whose etching speed with respect to metal is about 500 Å/min, may be used.

The metal layer removing slurry according to an embodiment of the present invention can selectively remove metal with respect to the sacrificial insulating layer. In particular, the metal layer removing slurry is not limited to the above-described slurry and various slurries known to those skilled in the art may be used for the CMP process performed on metal.

The first metal layer is for forming the lower electrode and the second metal layer is for forming the capping layer. According to an embodiment of the present invention, when the second metal layer is removed after a planarization process, it is preferable that the first metal layer be hardly etched. That is, the first metal layer and the second metal layer are simultaneously etched by the CMP process. However, the first and second metal layers preferably have an etching selectivity with respect to each other when the first metal layer and the second metal layer are etched by etching solution or etching gas. Therefore, the first metal layer and the second metal layer are preferably formed of different metal materials so as to have etching selectivity with respect to each other during dry etching or wet etching. Even if the first metal layer and the second metal layer are formed of the same metal, the first metal layer and the second metal layer are preferably formed by different deposition methods so as to have etching selectivity with respect to each other during the dry etching or the wet etching.

For example, ruthenium, titanium, a titanium nitride layer, tantalum, copper, tungsten, and aluminum may be used as the first metal layer and the second metal layer and the first meal layer and the second metal layer are not limited to the above. Two or more layers of the above-described metals may be laminated.

The second metal layer is selectively removed using a mixed solution including one or more compounds among hydrogen peroxide, ammonium peroxide, nitric acid, sulfuric acid, and acetic acid and ultra pure water. The mixed solution is not limited to the above. A process of selectively removing the second metal layer may be performed under the condition that the etching ratio of the second metal layer to the first metal layer is about 5:1 or more. The selective etching ability of the mixed solution is proportionate to temperature. The mixed solution may be in the range of between a room temperature and about 300° C.

Since the first metal layer and the second metal layer are made of different kinds of metal and are formed by different deposition methods and even if the first metal layer and the second metal layer are made of the same metal, the first metal layer and the second metal layer have an etching selectivity with respect to each other during the dry etching or the wet etching. Therefore, the second metal layer may be selectively removed by properly combining the above-described solutions.

As an example, when the first metal layer is formed of a ruthenium layer, a titanium nitride layer, a titanium layer, a structure obtained by laminating a titanium layer and a titanium nitride layer, a tantalum layer, or a combination of the above layers and the second metal layer is formed of a tungsten layer, an aluminum layer or a combination of the above layers, it is preferable that the second metal layer be selectively removed using a mixed solution of ultra pure water and hydrogen peroxide.

The method of forming the metal lower electrode, according to an embodiment of the present invention, may comprise forming an etching stop layer before forming the sacrificial insulating layer. Forming the aperture may comprise etching the sacrificial insulating layer until the etching stop layer is exposed and etching the exposed etching stop layer to expose the conductive region. When such an etching stop layer is used, it is possible to easily make the height of the formed aperture uniform on the entire wafer. That is, it is possible to easily make the height of the finally formed metal lower electrode uniform.

The etching stop layer is formed of an insulating layer including nitrogen atoms. For example, the etching stop layer is formed of a SiN layer, a SiBN layer, or a BN layer and is not limited to the above.

The method of forming the metal lower electrode, according to an embodiment of the present invention, may comprise, after removing the second metal layer, removing the sacrificial insulating layer to expose the outer walls of the first metal layer, forming a dielectric layer along the inner walls and the outer walls and the top surface of the first metal layer, and sequentially forming an upper electrode layer on the dielectric layer. Therefore, the capacitor having the metal lower electrode is completed.

The dielectric layer may be formed of an oxide layer, a nitride layer, or a high dielectric layer having high dielectric constant. The upper electrode layer may be silicon or metal or a structure obtained by laminating metal and silicon.

A silicon layer may be further formed before forming the first metal layer. In such a case, the lower electrode has a structure obtained by laminating a silicon layer and the first metal layer.

The method of forming the metal lower electrode according to an embodiment of the present invention can be matched to a metal wiring line process. That is, when the aperture that confines the lower electrode is formed in the sacrificial insulating layer in a first region, for example, the cell region, a wiring line damascene and a via hole are simultaneously formed in a second region, for example, the peripheral circuit region. A titanium layer or a structure obtained by laminating a titanium layer and a titanium nitride layer is formed as the first metal layer and copper or aluminum is formed as the second metal layer in the aperture, the wiring line damascene, and the via hole. The CMP process is performed on the second metal layer and the first metal layer until the sacrificial insulating layer is exposed. Therefore, a capacitor lower electrode is completed in the cell region and a metal wiring line is completed in the peripheral circuit region. In subsequent processes, the second metal and the sacrificial insulating layer that reside in the aperture in the cell region are removed.

That is, the CMP process according to the present invention is also used as the planarization process in a common wiring line process. Therefore, the method of forming the metal lower electrode according to an embodiment of the present invention can be matched to the wiring line process without an additional process.

A method of forming the metal wiring line and the capacitor metal lower electrode according to an embodiment of the present invention comprises forming a sacrificial insulating layer on a semiconductor substrate including a first conductive region in a cell region and a second conductive region in a peripheral circuit region, forming a first aperture that exposes the first conductive region and a second aperture that exposes the second conductive region, forming a first metal layer and a second metal layer on the sacrificial insulating layer such that the first aperture and the second aperture are filled with the first metal layer and the second metal layer, planarizing the second metal layer and the first metal layer until the sacrificial insulating layer is exposed, and removing the remaining second metal layer and the sacrificial insulating layer from the cell region.

The second aperture may comprise a groove that receives a metal wiring line and a via-hole connected to the groove to expose the second conductive region.

When the second aperture is the via-hole, the planarization process is performed to form a via-plug in the peripheral circuit region and then, a subsequent process is performed to form the metal wiring line. That is, after removing the second metal layer and the sacrificial insulating layer from the cell region, a wiring line material is deposited and is patterned to form the metal wiring line electrically connected to the via plug formed in the second aperture in the peripheral circuit region.

When the second aperture is formed of the groove and the via-hole, the metal wiring line and the via-hole are simultaneously formed in the peripheral circuit region in the planarization process.

According to an embodiment of the present invention, a method of selectively removing the metal layer is applied to the method of forming the metal lower electrode in which the capping layer is made of metal. A method of selectively removing a metal layer according to an embodiment of the present invention comprises forming a first metal layer including a ruthenium layer, a titanium nitride layer, a titanium layer, a structure obtained by laminating a titanium layer and a titanium nitride layer, a tantalum layer or a combination of the above layers on a substrate, forming a second metal layer made of a tungsten layer, an aluminum layer or a combination of the above layers on the first metal layer, and selectively removing the second metal layer using a mixed solution of ultra pure water and hydrogen peroxide.

### BRIEF DESCRIPTION OF THE DRAWINGS

Preferred embodiments of the present invention can be understood in more detail from the following description, taken in conjunction with the accompanying drawings in which:

FIGS. 1 to 4 are sectional views illustrating a conventional method of forming a capacitor having a metal lower electrode on a semiconductor substrate;

FIGS. 5 to 9 are sectional views illustrating a method of forming a metal lower electrode on a semiconductor substrate according to an embodiment of the present invention;

FIGS. 10 to 12 are sectional views illustrating a method of forming a metal lower electrode on a semiconductor substrate according to an embodiment of the present invention;

FIGS. 13 to 17 are sectional views illustrating a method of forming a capacitor and a metal wiring line on a semiconductor substrate according to an embodiment of the present invention; and

FIGS. 18 to 21 are sectional views illustrating a method of forming a capacitor and a metal wiring line on a semiconductor substrate according to an embodiment of the present invention.

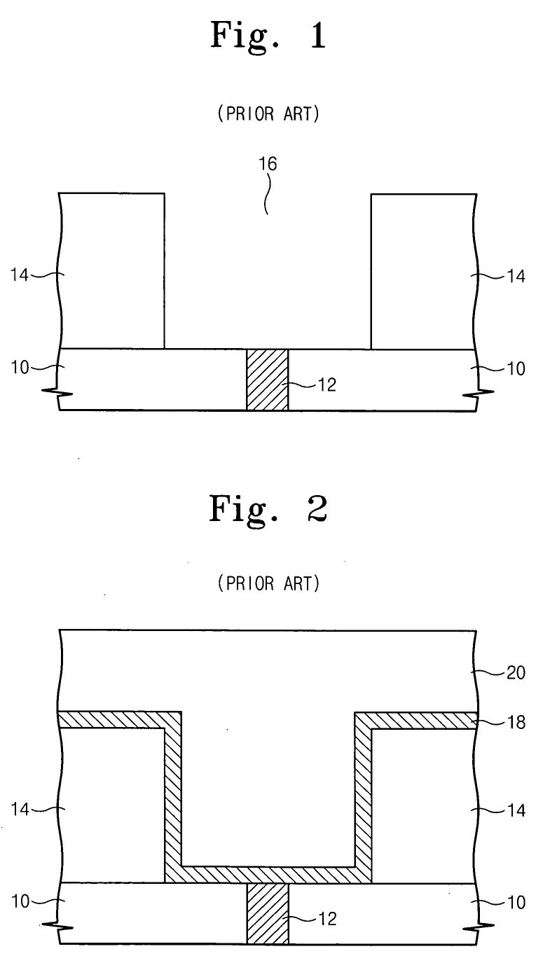

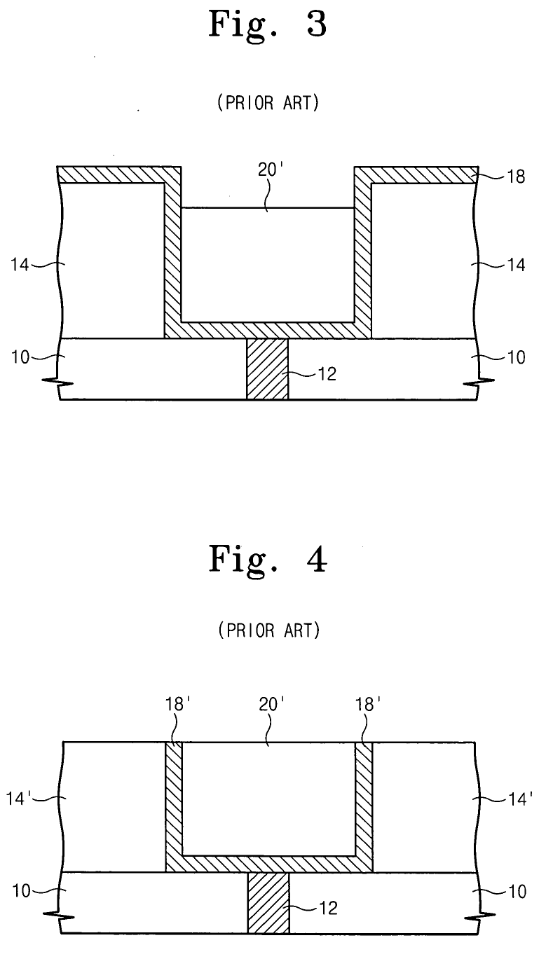

### DETAILED DESCRIPTION OF PREFERRED EMBODIMENTS

Preferred embodiments of the present invention now will be described more fully with reference to the accompanying drawings. This invention may, however, be embodied in many different forms and should not be construed as being limited to the embodiments set forth herein. Rather, these embodiments are provided so that this disclosure will be thorough and complete, and will fully convey the scope of the invention to those skilled in the art. It will also be understood that when a layer is referred to as being on another layer or substrate, it can be directly on the other layer or substrate, or intervening layers may also be present. In the drawings, the thickness of layers and regions are exaggerated for clarity.

The present disclosure relates to a method of forming a lower electrode of a capacitor. Description of an element separating process, a transistor forming process, and a bit line forming process that are performed in common semiconductor manufacturing processes will be omitted.

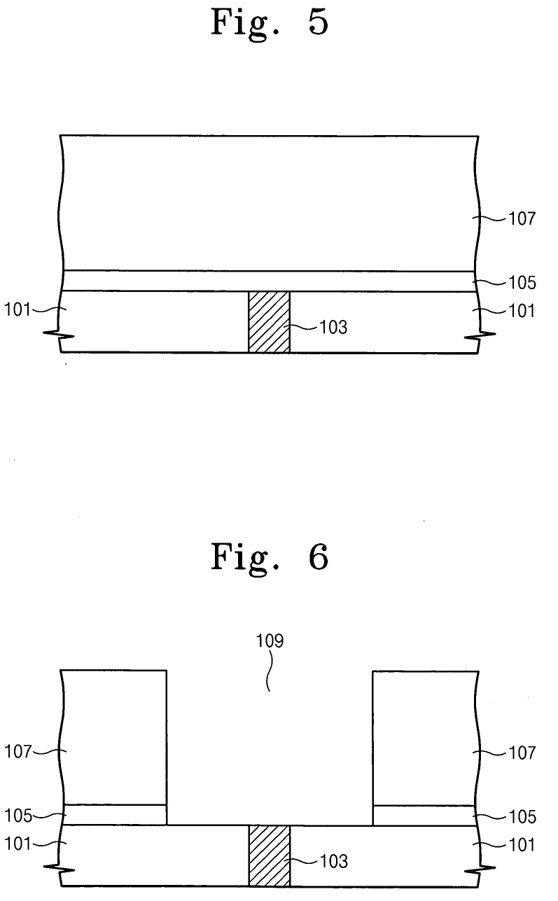

First, a method of forming a metal lower electrode according to an embodiment of the present invention will be described with reference to FIGS. 5 to 9. In order to facilitate understanding of the embodiments of the present invention, in the drawings, only one lower electrode is shown and other elements such as a transistor and bitlines are not shown.

Referring to FIG. 5, an interlayer insulating layer 101 including a conductive region such as a contact plug 103 is formed on a substrate (not shown). As is known, an element separating process, a transistor forming process, and a bit line process are commonly performed before forming the contact plug 103. For example, the contact plug 103 is electrically connected to the source of the transistor and the bit line is connected to the drain of the transistor. The interlayer insulating layer 101 is formed of an oxide layer using a known thin film deposition process. A patterning process is performed on the interlayer insulating layer 101 and a deposition process and a planarization process are performed on a conductive material to form the contact plug 103.

Subsequently, referring to FIG. 5, an etching stop layer 105 as a selection layer is formed on the interlayer insulating layer 101 and the contact plug 103. Then, a sacrificial insulating layer 107 that determines the height of the capacitor lower electrode is formed on the etching stop layer 105. The etching stop layer 105 and the sacrificial insulating layer 107 are formed of layers having etching selectivity with respect to each other. In other words, one of the two layers can be selectively etched when a specific etching gas or etching solution is used. Although the two layers may have etching selectivity when etched with a predetermined etching gas or etching solution, the two layers may not have etching selectivity when a predetermined slurry is used in a chemical mechanical polishing (CMP) process.

The etching stop layer 105 may be formed of a layer containing nitrogen atoms. The sacrificial oxide layer 107 may be formed of a layer containing oxygen atoms. For example, the etching stop layer 105 is formed of a SiN layer, a SiBN layer, or a BN layer and is not limited to same. The sacrificial insulating layer 107 may be formed of a silicon oxide layer using a common thin film deposition process. For example, the sacrificial insulating layer 107 may be formed of an oxide layer such as plasma enhanced tetra-ethyl-ortho-silicate (PETEOS), boro-phospho-silicate-glass (BPSG), plasma enhanced oxide (PEOX), and undoped silicate glass (USG) or a combination of the above and is not limited to same.

Next, referring to FIG. 6, a photolithography etching process is performed to anisotropically etch the sacrificial insulating layer 107 and the etching stop layer 105 such that an aperture 109 that exposes the contact plug 103 and the interlayer insulating layer 101 on both sides of the contact plug 103 is formed. The aperture 109 confines the lower electrode. To be specific, after etching the sacrificial insulating layer 107 until the etching stop layer 105 is exposed, the exposed etching stop layer 105 is etched until the contact plug 103 and the interlayer insulating layer 101 are exposed. Therefore, when the etching stop layer 105 is used, it is possible to make the depth of the formed aperture 109 uniform over the entire wafer.

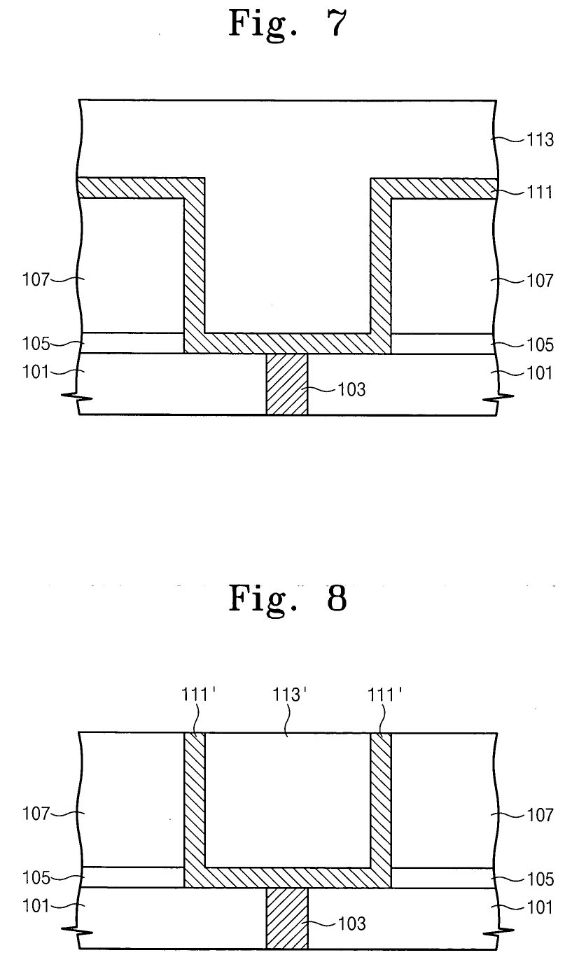

Next, referring to FIG. 7, a first metal layer 111, to be used as the lower electrode, is formed along the sides and the bottom of the aperture 109 and the top surface of the sacrificial insulating layer 107. Subsequently, in order to prevent the first metal layer 111 from being etched and to prevent defects from being generated in the aperture 109 in a subsequent planarization process, a second metal layer 113 as the capping layer is formed on the first metal layer 111.

The first metal layer 111 and the second metal layer 113 have etching selectivity when etched with a predetermined etching solution or etching gas. However, the two metal layers do not have etching selectivity when the slurry is used in the CMP process. That is, since the first metal layer 111 and the second metal layer 113 are metals, the first metal layer 111 and the second metal layer 113 are simultaneously planarized by predetermined slurries in the CMP process.

For example, the first metal layer 111 and the second metal layer 113 may be formed of different kinds of metal layers or by different deposition methods. Ruthenium, titanium, a titanium nitride layer, tantalum, copper, tungsten, and aluminum may be used as the first metal layer 111 and the second metal layer 113. It is to be understood that the first metal layer 111 and the second metal layer 113 are not limited to the above materials. Also, a combination of the above-described metal layers may be used as the first metal layer 111 and the second metal layer 113. The first metal layer 111 is preferably formed of ruthenium, a titanium nitride layer, titanium, a structure obtained by laminating a titanium layer and a titanium nitride layer, a tantalum layer or a combination of the above. The second metal layer 113 is preferably formed of tungsten, aluminum or a combination of the above.

Next, referring to FIG. 8, a planarization process such as the CMP process is performed to selectively planarize the second metal layer 113 and the first metal layer 111 with respect to the sacrificial insulating layer 107. That is, the second metal layer 113 and the first metal layer 111 are planarized until the sacrificial insulating layer 107 is exposed such that the second metal layer and the first metal layer outside the aperture 109 are removed. Therefore, the first metal layer 111′ and the second metal layer 113′ are left only in the aperture 109. The first metal layer 111′ that resides in the aperture 109 becomes the lower electrode.

The second metal layer and the first metal layer are metals such that the second metal layer and the first metal layer can be simultaneously etched using the same metal removing slurry. The second metal layer and the first metal layer can be selectively planarized with respect to an oxide layer (that is, the sacrificial insulating layer 107). The metal removing slurry according to an embodiment of the present invention includes an oxidizer and an abrasive. Hydrogen peroxide may be used as the oxidizer that oxidizes metal. Al₂O₃ or SiO₂ may be used as the abrasive. The abrasive applies physical and mechanical force to oxidized metal together with pressure provided by a pad such that the oxidized metal is separated from the substrate. The metal removing slurry may further include sulfuric acid, nitric acid, and hydrochloric acid as a pH controller. The pH controller facilitates the oxidization of metal.

For example, the slurry having a range of between about pH 1 and about pH 5, whose etching ratio of the sacrificial insulating layer to metal is about 1:10 or more and whose etching speed with respect to metal is about 500 Å/min, may be used.

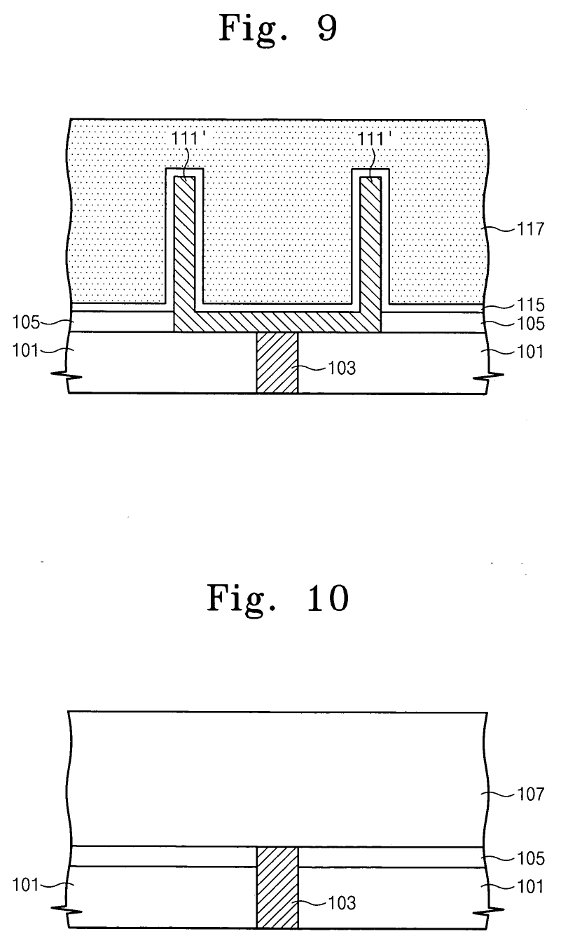

Next, referring to FIG. 9, the second metal layer 113′ that resides in the sacrificial insulating layer 107 and the aperture 109 is removed such that the inner walls and the outer walls of the first metal layer 111′ are exposed. At this time, the first metal layer 111′ is not removed. The sacrificial insulating layer 107 may be removed using a common oxide layer removing etching solution. The second metal layer 113′ is removed using a mixed solution including one or more compounds among hydrogen peroxide, ammonium peroxide, nitric acid, sulfuric acid, and acetic acid and ultra pure water. The mixed solution is preferably selected such that the etching ratio of the first metal layer to the second metal layer is about 1:5. For example, when the first metal layer 111 is formed of a ruthenium layer, a titanium nitride layer, a titanium layer, a structure obtained by laminating a titanium layer and a titanium nitride layer, or a tantalum layer, or a combination of the above layers and the second metal layer 113 is formed of a tungsten layer or an aluminum layer or a combination of the above layers, it is preferable that the second metal layer 113 be selectively removed using a mixed solution of ultra pure water and hydrogen peroxide. The temperature of the mixed solution may be in a range between room temperature and about 300° C.

Subsequently, referring to FIG. 9, a dielectric layer 115 is formed on the surface of the exposed first metal layer 111′ and on the interlayer insulating layer 101 and then, the upper electrode layer 117 is formed. The upper electrode layer 117 may be formed of, for example, silicon, a metal layer, or a structure obtained by laminating a metal layer and silicon.

Next, referring to FIGS. 10 to 12, a method of forming a metal capacitor lower electrode according to another embodiment of the present invention will be described. According to the method described with reference to FIGS. 5 to 9, the etching stop layer 105 is formed after the contact plug 103 is formed. According to the present embodiment, the etching stop layer 105 is formed before forming the contact plug 103 and the remaining processes are the same.

First, referring to FIG. 10, the interlayer insulating layer 101 and the etching stop layer 105 are formed on a semiconductor substrate (not shown). As described above, before forming the interlayer insulating layer 101, an element separating process, a transistor forming process, and a bit line forming process that are common processes are performed.

Subsequently, after the etching stop layer 105 and the interlayer insulating layer 101 are patterned to form a contact hole, a conductive material is formed to form the contact plug 103. That is, the contact plug 103 is formed in the etching stop layer 105 and the interlayer insulating layer 101. Referring to FIG. 10, the sacrificial insulating layer 107 that determines the height of the lower electrode is formed on the contact plug 103 and the etching stop layer 105.

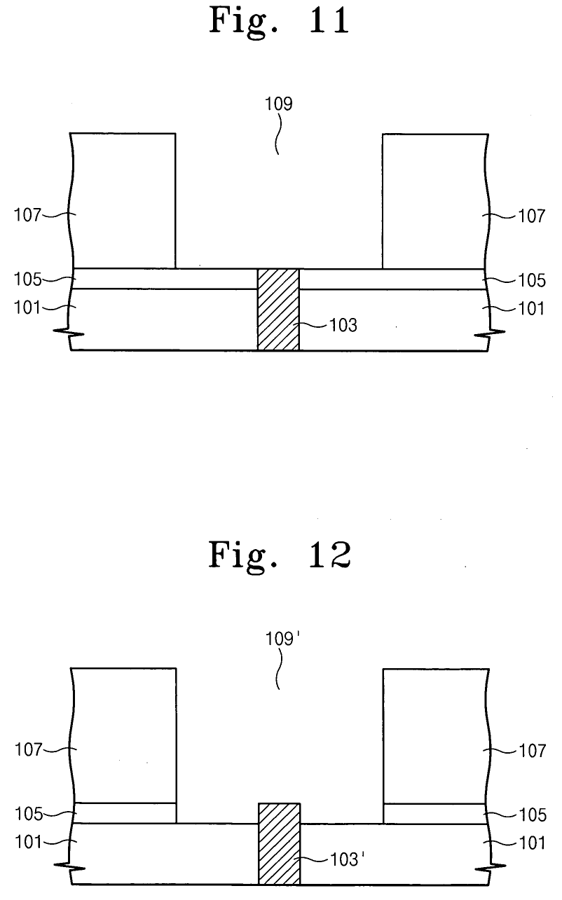

Next, referring to FIG. 11, the sacrificial insulating layer 107 is etched until the etching stop layer 105 and the contact plug 103 are exposed to form the aperture 109 that confines the lower electrode.

Next, referring to FIG. 12, the exposed etching stop layer 105 is removed to expose the interlayer insulating layer 101. As a result, a part of the upper side of the contact plug 103′ is exposed and the contact plug 103′ protrudes above the surface of the interlayer insulating layer 101 such that the size of the protrusion corresponds to the thickness of the removed etching stop layer. Therefore, the area of the inner surface of the final contact hole 109′ increases such that the area of the lower electrode is increased.

Subsequent processes are the same as the above-described processes. That is, after forming the first metal layer and the second metal layer, the CMP process is performed on the second metal layer and the first metal layer. Subsequently, after the second metal layer that resides in the aperture is removed and then, the sacrificial insulating layer is removed, the dielectric layer and the upper metal layer are formed.

Hereinafter, a method of forming the capacitor in the cell region and of forming the metal wiring line in the peripheral circuit region, wherein the above-described method of forming the metal lower electrode for the capacitor is uses, will be described. The CMP process of the above-described method of forming the metal lower electrode is simultaneously applied as the CMP process for forming the via-plug or the metal wiring line.

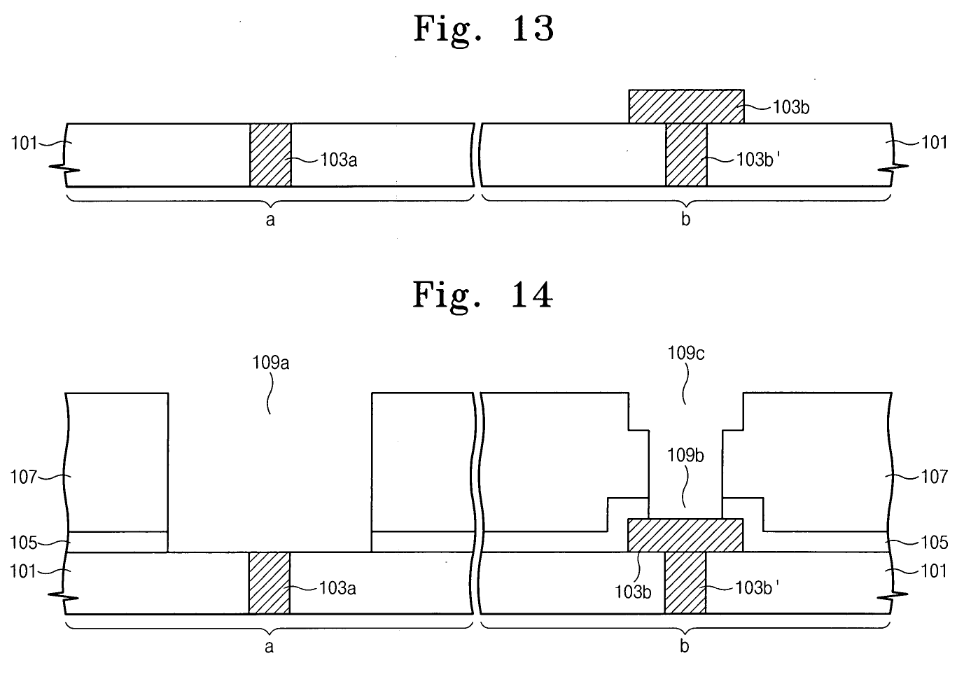

The method of forming the capacitor in the cell region and of forming the metal wiring line in the peripheral circuit region using the above-described method of forming the metal lower electrode for the capacitor will be described with reference to FIGS. 13 to 17. Designations “a” and “b” at the bottom of FIGS. 13 to 17 denote the cell region and the peripheral circuit region, respectively.

First, referring to FIG. 13, the interlayer insulating layer 101 including a first conductive region 103a and a second conductive region 103b is formed on a semiconductor substrate (not shown). The first conductive region 103a is formed in the cell region and is used as a contact plug that connects the capacitor lower electrode, to be formed in subsequent steps, to the active region of the semiconductor substrate. The second conductive region 103b is the lower metal wiring line that is formed in the peripheral circuit region and is electrically connected to the active region of the semiconductor substrate through the lower conductive plug 103b′.

After forming the interlayer insulating layer 101 on the semiconductor substrate, contact holes are formed in the cell region and in the peripheral circuit region and a conductive material is formed in the contact holes such that the contact plug 103a and the conductive plug 103b′ are formed. Subsequently, the lower metal wiring line 103b, which is electrically connected to the conductive plug 103b′ in the peripheral circuit region, is formed. Also, the lower metal wiring line 103b and the conductive plug 103b′ may be simultaneously formed in the peripheral circuit region by a damascene process.

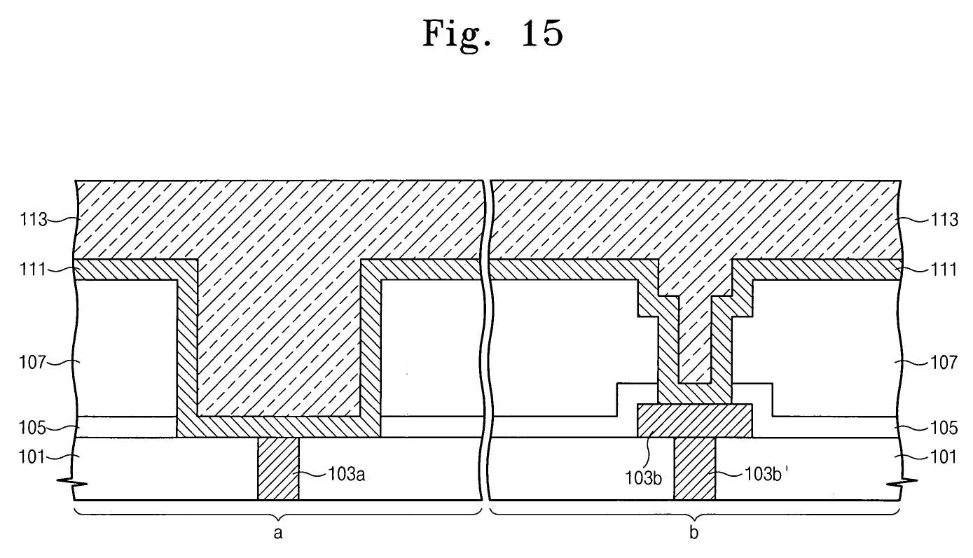

Next, referring to FIG. 14, the etching stop layer 105 as a selection layer is formed on the contact plug 103a, the lower metal wiring line 103b, and the interlayer insulating layer 101. Subsequently, the sacrificial insulating layer 107 is formed on the etching stop layer 105. Subsequently, the sacrificial insulating layer 107 and the etching stop layer 105 are patterned to form a first aperture 109a that exposes the contact plug 103a in the cell region and second apertures 109b and 109c that expose the lower metal wiring line 103b in the peripheral circuit region. The first aperture 109a in the cell region confines the lower electrode and is formed such that the contact plug 103a and a part of the interlayer insulating layer on both sides are exposed. On the other hand, the second apertures 109b and 109c in the peripheral circuit region are comprised of a linear groove 109c that holds the upper metal wiring line and the via hole 109b connected to the groove 109c for exposing the lower metal wiring line 103b. The second apertures are formed by the damascene process.

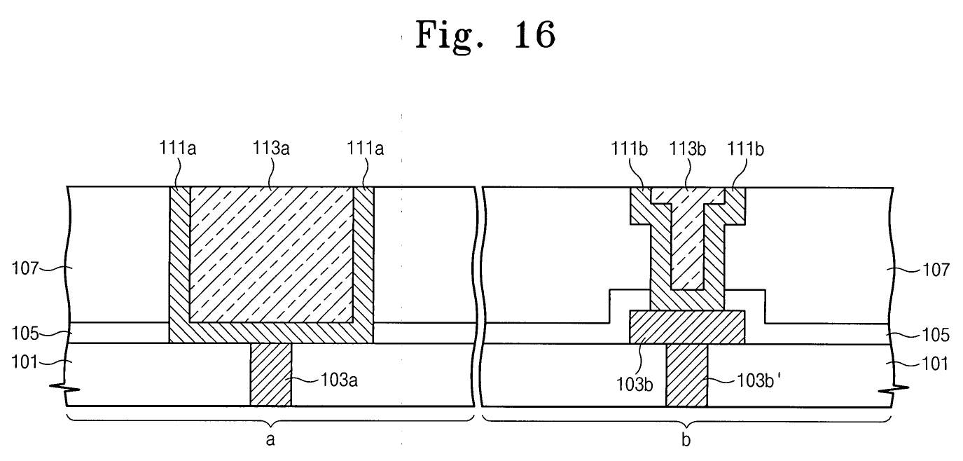

Next, referring to FIGS. 15-16, the first metal layer 111 and the second metal layer 113 are formed in the cell region and the peripheral circuit region, respectively. The first metal layer 111 is used as the metal lower electrode 111a in the cell region and is used as a structure obtained by laminating a barrier and an adhesive layer in the peripheral circuit region (111b). The second metal layer 113 is removed from the cell region in a subsequent process, but a portion thereof is used as the upper metal wiring line (113b), located in the groove 109c of the peripheral circuit region. A via-plug including portions of the first metal layer and second metal layer (111b and 113b) is formed in via hole 109b. The first metal layer 111 is formed of metal suitable for being used as the structure obtained by laminating an adhesive layer and a barrier layer (111b). For example, the first metal layer 111 is formed of a titanium nitride layer, a titanium layer, a structure obtained by laminating a titanium layer and a titanium nitride layer, or a tantalum layer or a combination of the above layers. The second metal layer 113 is formed of metal suitable for being used as the metal wiring line, for example, tungsten or aluminum or a combination of the above.

Next, referring to FIG. 16, the CMP process is performed to form the metal lower electrode 111a that is electrically separated from adjacent lower electrodes in the cell region and to form an upper metal wiring line (113b) that is electrically separated from adjacent wiring lines in the peripheral circuit region. The CMP process is performed on the second metal layer 113 and the first metal layer 111 using the sacrificial insulating layer 107 as a planarization stop layer. In the CMP process, the second metal layer 113 and the first metal layer 111 are simultaneously planarized.

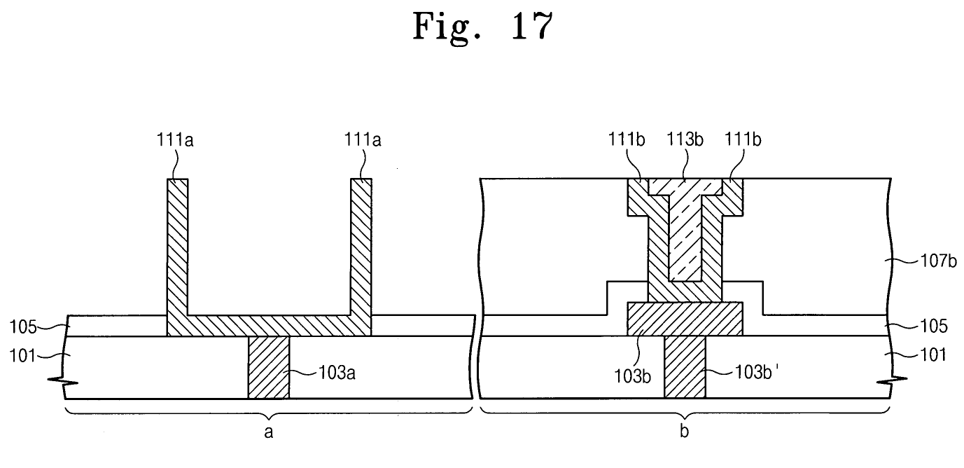

Next, referring to FIG. 17, the second metal layer 113a that resides in the first aperture and the sacrificial insulating layer 107 are removed from the cell region such that the inner walls and the outer walls of the metal lower electrode 111a are exposed. The second metal layer 113a is selectively removed using a mixed solution of ultra pure water and hydrogen peroxide. At this time, the peripheral circuit region is protected by photoresist. In a subsequent process, the dielectric layer and the upper electrode layer are formed on the semiconductor substrate.

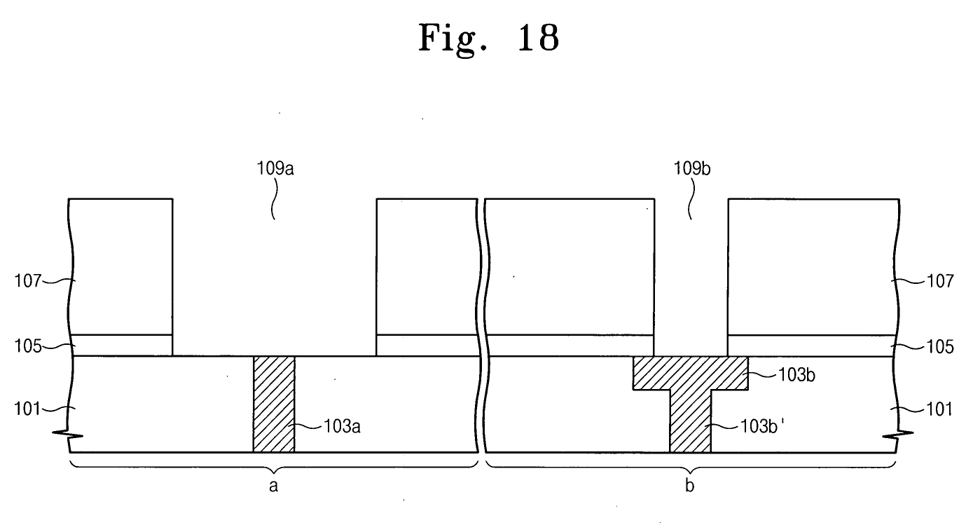

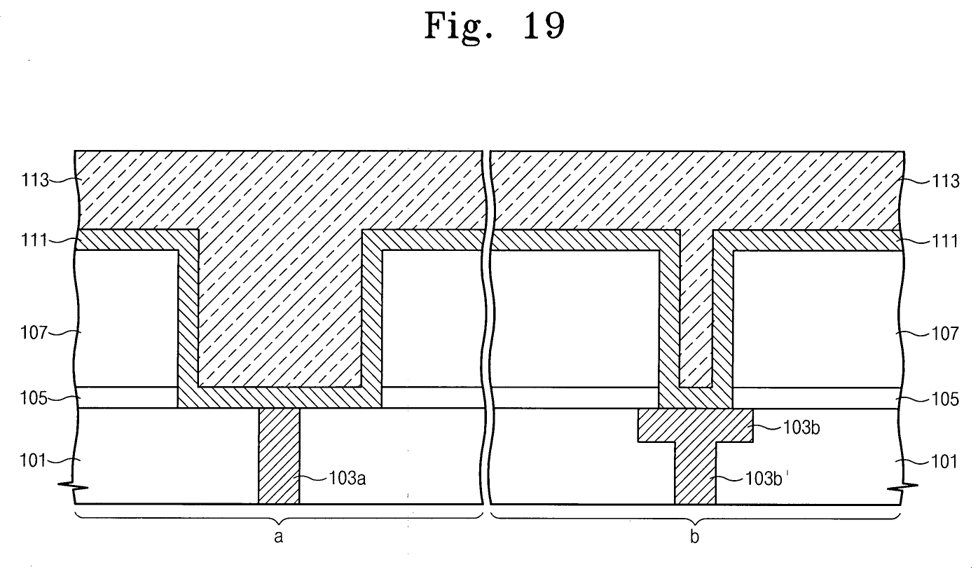

Next, referring to FIGS. 18 to 21, a method of simultaneously forming the metal lower electrode and the metal wiring line according to another embodiment of the present invention, in which the method of forming the lower electrode for the capacitor described with reference to FIGS. 5 to 9 is used, will be described. Designations “a” and “b” at the bottom of FIGS. 18 to 21 denote the cell region and the peripheral circuit region, respectively.

Unlike in the method described with reference to FIGS. 13 to 17, according to the present embodiment, when the first aperture 109a for the lower electrode is formed in the cell region, a via hole 190b is formed in the peripheral circuit region. According to the method described with reference to FIGS. 13 to 17, a groove for the upper metal wiring line as well as the via hole is formed in the peripheral circuit region.

First, referring to FIG. 18, as described in the above method, the contact plug 103a is formed in the interlayer insulating layer 101 of the cell region. Similarly, the conductive plug 103b′ and the lower metal wiring line 103b are formed in the interlayer insulating layer 101 of the peripheral circuit region. Subsequently, the etching stop layer 105 and the sacrificial insulating layer 107 are formed on the inter layer insulating layer 101, contact plug 103a and the lower metal wiring line 103b. The sacrificial insulating layer 107 and the etching stop layer 105 are patterned to form the first aperture 109a in the cell region and to form the second aperture 109b in the peripheral circuit region.

The first aperture 109a of the cell region confines the lower electrode and is formed such that the contact plug 103a and a part of the interlayer insulating layer on both sides of the contact plug 103a are exposed. The second aperture 109b of the peripheral circuit region is used as the via-hole that exposes the lower metal wiring line 103b.

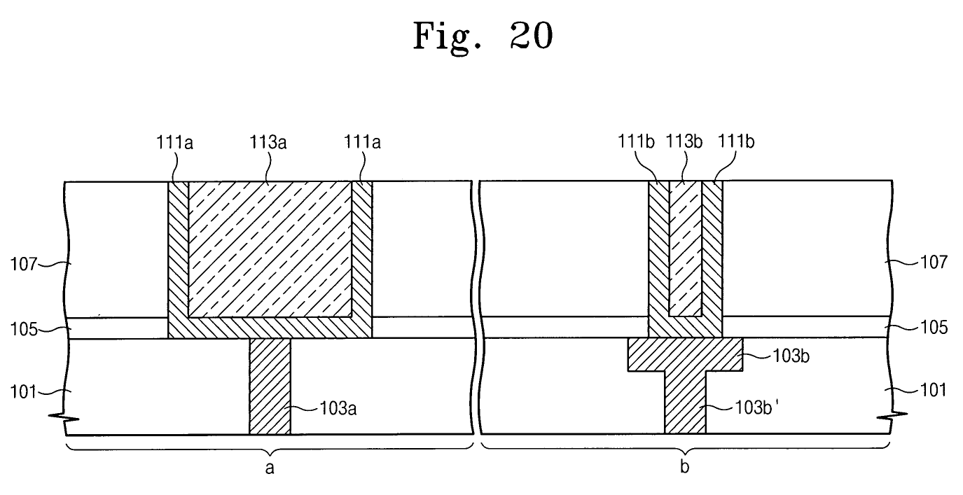

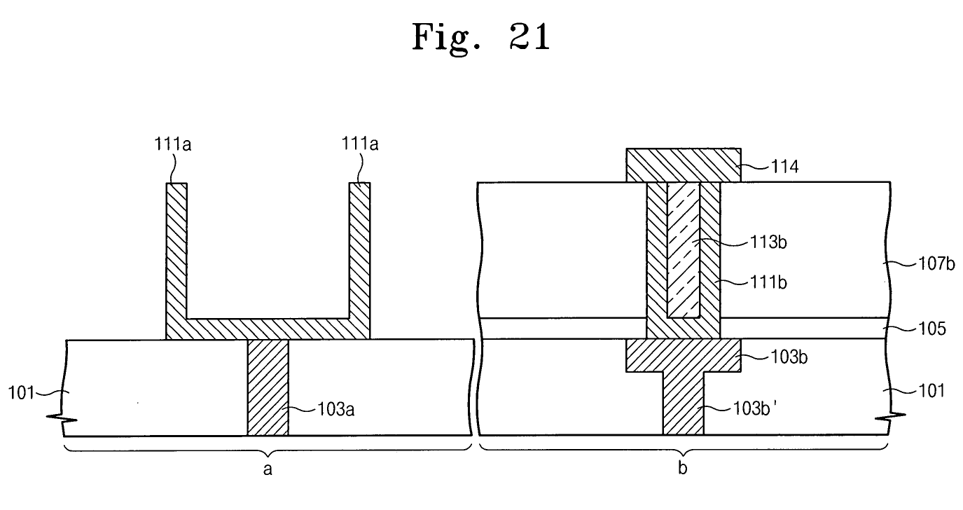

Next, referring to FIGS. 19-20, the first metal layer 111 and the second metal layer 113 are formed in the cell region and the peripheral circuit region, respectively. The first metal layer is used as the metal lower electrode 111a in the cell region and is used as a structure obtained by laminating a barrier layer and an adhesive layer in the peripheral circuit region (111b). The second metal layer is removed from the cell region, but is used to form part of the via plug in the peripheral circuit region. The first metal layer 111 is formed of metal suitable for being used as the structure obtained by laminating an adhesive layer and a barrier layer (111b). For example, the first metal layer 111 is formed of a titanium nitride layer, a titanium layer, a structure obtained by laminating a titanium layer and a titanium nitride layer, or a tantalum layer or a combination of the above layers. The second metal layer 113 is formed of metal suitable for being used as a metal wiring line, for example, tungsten or aluminum or a combination of the above.

Next, referring to FIG. 20, the CMP process is performed to form a metal lower electrode 111a that is electrically separated from adjacent lower electrodes in the cell region and to form the plug formed of the first metal layer 111b and the second metal layer 113b in the peripheral circuit region. The CMP process is performed on the second metal layer and the first metal layer using the sacrificial insulating layer 107 as a planarization stop layer. In the CMP process, the second metal layer and the first metal layer are simultaneously planarized.

Next, referring to FIG. 21, the second metal layer 113a that resides in the first aperture and the sacrificial insulating layer 107 are removed from the cell region such that the inner walls and the outer walls of the metal lower electrode 111a are exposed. The second metal layer 113a is selectively removed using a mixed solution of ultra pure water and hydrogen peroxide. At this time, the peripheral circuit region is protected by a photoresist. Subsequently, an upper metal wiring line 114 that is electrically connected to the via-plug of the peripheral circuit region is formed.

In a subsequent process, the dielectric layer and the upper electrode layer are formed on the semiconductor substrate.

In the method of forming the metal lower electrode according to embodiments of the present invention, the adjacent lower electrodes are electrically separated from each other by performing the CMP process once. Therefore, the processes are simplified compared with the conventional art and the problems that occur due to the etchback process performed on the capping layer in the conventional art do not occur.

Also, the method of forming the metal lower electrode according to the embodiments of the present invention can be matched to the metal wiring line process without an additional process.

Although the illustrative embodiments have been described herein with reference to the accompanying drawings, it is to be understood that the present invention is not limited to those precise embodiments, and that various other changes and modifications may be affected therein by one of ordinary skill in the related art without departing from the scope or spirit of the invention. All such changes and modifications are intended to be included within the scope of the invention as defined by the appended claims.

1. A method of forming a lower electrode of a capacitor, the method comprising:
forming a sacrificial insulating layer on a semiconductor substrate including a conductive region;
patterning the sacrificial insulating layer to form an aperture exposing the conductive region;
forming a first metal layer along the sides and the bottom of the aperture and on a top surface of the sacrificial insulating layer;
forming a second metal layer on the first metal layer, whereby the aperture is filled with the second metal layer;
performing a planarization process on the second metal layer and the first metal layer until the sacrificial insulating layer is exposed; and
selectively removing the second metal layer residing in the aperture for exposing inner walls of the first metal layer.

2. The method as set forth in claim 1, wherein the first metal layer and the second metal layer are each formed of ruthenium, titanium, a titanium nitride layer, tantalum, copper, tungsten, aluminum, or a combination of thereof.

3. The method as set forth in claim 2, wherein the first metal layer and the second metal layer are formed of the same material and by different deposition methods for causing the first metal layer and the second metal layer to have an etching selectivity with respect to each other.

4. The method as set forth in claim 2, wherein the first metal layer and the second metal layer are formed of different materials for causing the first metal layer and the second metal layer to have an etching selectivity with respect to each other.

5. The method as set forth in claim 1, further comprising forming an etching stop layer prior to forming the sacrificial layer, wherein forming the aperture comprises:
etching the sacrificial insulating layer until the etching stop layer is exposed; and
etching the exposed etching stop layer to expose the conductive region.

6. The method as set forth in claim 5, wherein the etching stop layer is formed of a SiN layer, a SiBN layer, or a BN layer.

7. The method as set forth in claim 1, wherein the second metal layer is selectively removed using a mixed solution including ultra pure water and one or more selected from a group consisting of hydrogen peroxide, ammonium peroxide, nitric acid, sulfuric acid, and acetic acid.

8. The method as set forth in claim 1, further comprising:
removing the sacrificial insulating layer for exposing outer walls of the first metal layer;
forming a dielectric layer along the inner walls, the outer walls and a top surface of the first metal layer; and
forming an upper electrode layer on the dielectric layer.

9. The method as set forth in claim 1,
wherein the first metal layer is formed of a ruthenium layer, a titanium nitride layer, a titanium layer, a structure obtained by laminating a titanium layer and a titanium nitride layer, a tantalum layer, or a combination thereof,
wherein the second metal layer is formed of a tungsten layer, an aluminum layer or a combination thereof, and
wherein the second metal layer is selectively removed using a mixed solution of ultra pure water and hydrogen peroxide.

10. The method as set forth in claim 6,
wherein the first metal layer is formed of a ruthenium layer, a titanium nitride layer, a titanium layer, a structure obtained by laminating a titanium layer and a titanium nitride layer, a tantalum layer or a combination thereof,
wherein the second metal layer is formed of a tungsten layer, an aluminum layer or a combination thereof, and
wherein the second metal layer is selectively removed using a mixed solution of ultra pure water and hydrogen peroxide.

11. A method of forming a lower electrode of a capacitor, the method comprising:
forming an interlayer insulating layer including a contact plug on a substrate;
forming a sacrificial insulating layer on the interlayer insulating layer;
patterning the sacrificial insulating layer to form an aperture for exposing the contact plug and the interlayer insulating layer on both sides of the contact plug;
forming a first metal layer to be used as a lower electrode on the sides and the bottom of the aperture and on the sacrificial insulating layer;
forming a second metal layer having an etching selectivity with respect to the first metal layer on the first metal layer, whereby the aperture is filled with the second metal layer;
performing a planarization process on the second metal layer and the first metal layer until the sacrificial insulating layer is exposed; and
removing the second metal layer residing in the aperture.

12. The method as set forth in claim 11, wherein the first metal layer and the second metal layer are formed of different materials and are each formed of ruthenium, titanium, a titanium nitride layer, tantalum, copper, tungsten, aluminum or combinations thereof.

13. The method as set forth in claim 11, wherein the first metal layer and the second metal layer are formed of the same material and by different deposition methods and are formed of ruthenium, titanium, a titanium nitride layer, tantalum, copper, tungsten, aluminum or combinations thereof.

14. The method as set forth in claim 11, further comprising forming an etching stop layer before forming the sacrificial insulating layer, wherein forming the aperture comprises:
etching the sacrificial insulating layer until the etching stop layer is exposed; and
etching the exposed etching stop layer.

15. The method as set forth in claim 11, wherein forming the interlayer insulating layer including the contact plug comprises:
sequentially forming an oxide layer and an etching stop layer on the substrate;
sequentially patterning the etching stop layer and the oxide layer to form a contact hole;
filling the contact hole with a conductive material; and
planarizing the conductive material until the etching stop layer is exposed, and
wherein forming the aperture comprises:
etching the sacrificial insulating layer until the etching stop layer is exposed; and
etching the etching stop layer until the oxide layer is exposed.

16. The method as set forth in claim 14, wherein the etching stop layer is formed of a SiN layer, a SiBN layer, or a BN layer.

17. The method as set forth in claim 11, wherein the second metal layer is selectively removed using a mixed solution including ultra pure water and one or more compounds selected from a group consisting of hydrogen peroxide, ammonium peroxide, nitric acid, sulfuric acid, and acetic acid, wherein the etching ratio of the first metal layer to the second metal layer is greater than or equal to about 1:5.

18. The method as set forth in claim 11, further comprising:
removing the sacrificial insulating layer for exposing outer walls of the first metal layer;
forming a dielectric layer along inner walls and the outer walls and a top surface of the first metal layer; and
forming an upper electrode layer on the dielectric layer.

19. The method as set forth in claim 11,
wherein the first metal layer is formed of a ruthenium layer, a titanium nitride layer, a titanium layer, a structure obtained by laminating a titanium layer and a titanium nitride layer, a tantalum layer or a combination thereof, and
wherein the second metal layer is formed of a tungsten layer, an aluminum layer or a combination thereof, and
wherein the second metal layer is selectively removed using a mixed solution of ultra pure water and hydrogen peroxide.

20. A method of selectively removing a metal layer, the method comprising:
forming a first metal layer on a substrate, the first metal layer including a ruthenium layer, a titanium nitride layer, a titanium layer, a structure obtained by laminating a titanium layer and a titanium nitride layer, a tantalum layer or a combination thereof;
forming a second metal layer on the first metal layer, the second metal layer including a tungsten layer, an aluminum layer or a combination thereof; and
selectively removing the second metal layer using a mixed solution of ultra pure water and hydrogen peroxide.

21. The method as set forth in claim 20, wherein a temperature of the mixed solution is in the range between a room temperature and about 300° C.

22. A method of manufacturing a semiconductor device, the method comprising:
forming a sacrificial insulating layer on a semiconductor substrate including a first conductive region in a cell region and a second conductive region in a peripheral circuit region;
forming a first aperture in the sacrificial insulating layer for exposing the first conductive region and a second aperture in the sacrificial insulating layer for exposing the second conductive region;
depositing a first metal layer and a second metal layer on the sacrificial insulating layer, whereby the first aperture and the second aperture are filled with the first metal layer and the second metal layer;
planarizing the second metal layer and the first metal layer until the sacrificial insulating layer is exposed; and
removing the remaining portions of the second metal layer and the sacrificial insulating layer from the cell region.

23. The method as set forth in claim 22,
wherein the first metal layer is formed of a ruthenium layer, a titanium nitride layer, a titanium layer, a structure obtained by laminating a titanium layer and a titanium nitride layer, a tantalum layer or a combination thereof,
wherein the second metal layer is formed of a tungsten layer, an aluminum layer or a combination thereof, and
wherein the second metal layer is selectively removed using a mixed solution of ultra pure water and hydrogen peroxide.

24. The method as set forth in claim 22, further comprising forming a metal wiring line electrically connected to a via plug formed in the second aperture in the peripheral circuit region after removing the second metal layer and the sacrificial insulating layer from the cell region.

25. The method as set forth in claim 22, wherein the second aperture comprises a groove for receiving a metal wiring line and a via-hole connected to the groove for exposing the second conductive region.
